(19) United States
(12) Patent Application Publication
(10) Pub. No.: US 2024/0334787 A1
(43) Pub. Date: Oct. 3, 2024

(54) DISPLAY DEVICE AND METHOD OF MANUFACTURING THE SAME

(71) Applicant: Samsung Display Co., LTD., Yongin-si (KR)

(72) Inventors: Jun Mo JI, Yongin-si (KR); Jun Su LEE, Yongin-si (KR)

(73) Assignee: Samsung Display Co., LTD., Yongin-si (KR)

(21) Appl. No.: 18/517,135

(22) Filed: Nov. 22, 2023

(30) Foreign Application Priority Data
Mar. 30, 2023 (KR) 10-2023-0041663

(51) Int. Cl. H10K 59/80; H10K 59/12

(52) U.S. Cl. CPC H10K 59/873; H10K 59/1201; H10K 2102/311

(57) ABSTRACT

A display device includes a display panel including light emitting elements, a panel support member disposed on a surface of the display panel, and a spacer disposed on a surface of the panel support member, the spacer including a first attachment layer, a support layer disposed on the first attachment layer, an outer peripheral film disposed on the first attachment layer and surrounding the support layer, and a second attachment layer disposed on the support layer and the outer peripheral film.

### CROSS-REFERENCE TO RELATED APPLICATION(S)

This application claims priority to and benefits of Korean Patent Application No. 10-2023-0041663 under 35 U.S.C. § 119, filed on Mar. 30, 2023 in the Korean Intellectual Property Office, the entire contents of which are herein incorporated by reference.

### BACKGROUND

### 1. Technical Field

The disclosure relates to a display device and a method of manufacturing the same.

### 2. Description of the Related Art

As information society develops, the demand for display devices for displaying images has increased and diversified. For example, display devices have been applied to various electronic devices such as smartphones, digital cameras, laptop computers, navigation devices, and smart televisions.

Recently, in order to increase portability of the display devices and provide wide display screens, various devices such as foldable display devices capable of folding a display area as well as rigid display devices have been released.

A display device may include a display panel including light emitting elements. The display device may include components such as a driving chip driving the light emitting elements, and such a driving chip may be formed as an integrated circuit (IC) and mounted on the display panel in a chip on glass (COG) manner, a chip on plastic (COP) manner, or an ultrasonic bonding manner.

The components such as the driving chip of the display device may be positioned below the display panel through bending of the display device, and a spacer for compensating for a height difference between members disposed below the display panel and the components such as the driving chip may be disposed.

### SUMMARY

Aspects of the disclosure provide a display device in which deformation of members disposed on and below a spacer is minimized by including an encapsulation-type spacer.

Aspects of the disclosure also provide a display device in which visibility of a spacer is improved.

Aspects of the disclosure also provide a method of manufacturing a display device capable of improving process efficiency and yield in a cutting process of a spacer.

However, aspects of the disclosure are not restricted to those set forth herein. The above and other aspects of the disclosure will become more apparent to one of ordinary skill in the art to which the disclosure pertains by referencing the detailed description of the disclosure given below.

According to an aspect of the disclosure, a display device may include a display panel including light emitting elements, a panel support member disposed on a surface of the display panel, and a spacer disposed on a surface of the panel support member, the spacer including a first attachment layer, a support layer disposed on the first attachment layer, an outer peripheral film disposed on the first attachment layer and surrounding the support layer, and a second attachment layer disposed on the support layer and the outer peripheral film.

In an embodiment, outer surfaces of the first attachment layer, the second attachment layer, and the outer peripheral film may be aligned with each other.

In an embodiment, the first attachment layer and the second attachment layer may have an area greater in size than an area of the support layer in plan view.

In an embodiment, outer surfaces of the first attachment layer and the second attachment layer may protrude beyond an outer surface of the support layer.

In an embodiment, the support layer may be spaced apart from the outer peripheral film, and the outer surface of the support layer may be disposed inside an inner surface of the outer peripheral film.

In an embodiment, a spaced distance between the support layer and the outer peripheral film is within about 0.5 mm.

In an embodiment, at least one of the first attachment layer, the second attachment layer, and the outer peripheral film may have a brightness quality different from a brightness quality of the panel support member.

In an embodiment, at least one of the first attachment layer, the second attachment layer, and the outer peripheral film may include a dye or a pigment having an opaque color.

In an embodiment, an entirety of a lower surface of the support layer may be in direct contact with an upper surface of the first attachment layer.

In an embodiment, the support layer may include an SUS metal.

In an embodiment, the display panel may include a first area, a second area, and a bending area between the first area and the second area, the bending area may be bent so that the second area is disposed below the first area, and the spacer may be disposed to overlap the first area and the second area in a thickness direction.

In an embodiment, the display device may further include a panel protection member disposed between the display panel and the panel support member, wherein the panel protection member may include a first panel protection member and a second panel protection member that are spaced apart from each other, the first panel protection member may be disposed on the first area, the second panel protection member may be disposed on the second area, and the first panel protection member and the second panel protection member may overlap the outer peripheral film and the support layer in the thickness direction.

In an embodiment, the second panel protection member may be disposed between the spacer and the second area.

In an embodiment, a size of the spacer may be smaller than a size of the panel support member, and the spacer may overlap a portion of the panel support member in the thickness direction and may be disposed adjacent to the bending area.

In an embodiment, the display device may further include a panel lower member disposed between the display panel and the panel support member, wherein the panel lower member may include at least one of a barrier layer and a cushion layer.

In an embodiment, the panel support member may include a metal plate.

In an embodiment, the support layer may have a hardness quality greater than a hardness quality of the first attachment layer, the second attachment layer, and the outer peripheral film.

According to an aspect of the disclosure, a display device may include a display panel including a display area including light emitting elements and a non-display area disposed around the display area, and a spacer disposed on a surface of the display panel. The spacer may include a first attachment layer, a support layer disposed on the first attachment layer, an outer peripheral film disposed on the first attachment layer and surrounding the support layer, and a second attachment layer disposed on the support layer and the outer peripheral film.

In an embodiment, outer surfaces of the first attachment layer and the second attachment layer may protrude beyond an outer surface of the support layer.

According to an aspect of the disclosure, a method of manufacturing a display device including a display panel including light emitting elements, a panel support member disposed on a surface of the display panel, and a spacer disposed on a surface of the panel support member may be provided. The method may include providing the spacer, and disposing the spacer on the display panel. The providing of the spacer may include providing a first attachment material layer, disposing an outer peripheral material layer and a support layer on the first attachment material layer, disposing a second attachment material layer on the outer peripheral material layer and the support layer, and simultaneously cutting the first attachment material layer, the outer peripheral material layer, and the second attachment material layer.

According to a display device according to an embodiment of the disclosure, deformation of members disposed on and below a spacer may be minimized by including an encapsulation-type spacer.

According to the display device according to an embodiment of the disclosure, visibility of a spacer may be improved.

According to a method of manufacturing a display device according to an embodiment of the disclosure, process efficiency and yield in a cutting process of a spacer may be improved.

The effects of the disclosure are not limited to the aforementioned effects, and various other effects are included in the specification.

### BRIEF DESCRIPTION OF THE DRAWINGS

The above and other aspects and features of the disclosure will become more apparent by describing in detail embodiments thereof with reference to the attached drawings, in which:

FIG. 1 is a schematic perspective view of a display device according to an embodiment in a first state;

FIG. 2 is a schematic perspective view of the display device according to an embodiment in a second state;

FIG. 3 is a schematic perspective view of a display device according to another embodiment in a first state;

FIG. 4 is a schematic perspective view of the display device according to another embodiment in a second state;

FIG. 5 is a schematic plan view of the display device according to an embodiment;

FIG. 6 is a schematic cross-sectional view taken along I-I′ of FIG. 5;

FIG. 7 is a schematic cross-sectional view of a display panel according to an embodiment;

FIG. 8 is a schematic cross-sectional view of the display device according to an embodiment in the second state;

FIG. 9 is a schematic cross-sectional view taken along line II-II′ of FIG. 5;

FIG. 10 is a schematic cross-sectional view illustrating a state in which the display device illustrated in FIG. 9 is bent;

FIG. 11 is a schematic perspective view of a spacer according to an embodiment;

FIG. 12 is an exploded schematic perspective view of the spacer according to an embodiment;

FIG. 13 is a schematic plan view of the spacer according to an embodiment;

FIG. 14 is a schematic bottom view of a display panel, a panel support member, and the spacer according to an embodiment;

FIG. 15 is a schematic cross-sectional view taken along line III-III′ of FIG. 14 in the second state;

FIG. 16 is a schematic plan view of a spacer according to still another embodiment;

FIG. 17 is a schematic cross-sectional view of the spacer according to still another embodiment;

FIG. 18 is a schematic plan view of a spacer according to still another embodiment;

FIG. 19 is a schematic cross-sectional view of the spacer according to still another embodiment;

FIG. 20 is a schematic perspective view of a display device according to still another embodiment;

FIG. 21 is a schematic cross-sectional view of the display device according to still another embodiment;

FIG. 22 is a flowchart illustrating a method of manufacturing a display device according to an embodiment;

FIG. 23 is a flowchart illustrating S100 of FIG. 22;

FIG. 24 is a schematic cross-sectional view illustrating S110 of FIG. 23;

FIG. 25 is a schematic cross-sectional view illustrating S120 of FIG. 23;

FIG. 26 is a schematic cross-sectional view illustrating S130 of FIG. 23; and

FIG. 27 is a schematic cross-sectional view illustrating S140 of FIG. 23.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, sizes, thicknesses, ratios, and dimensions of the elements may be exaggerated for ease of description and for clarity. Like numbers refer to like elements throughout.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean any combination including “A. B. or A and B.” The terms “and” and “or” may be used in the conjunctive or disjunctive sense and may be understood to be equivalent to “and/or.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

It will be understood that, although the terms first, second, etc., may be used herein to describe various elements, these elements should not be limited by these terms. These terms are only used to distinguish one element from another element. For example, a first element may be referred to as a second element, and similarly, a second element may be referred to as a first element without departing from the scope of the disclosure.

It will also be understood that when a layer is referred to as being “on” another layer or substrate, it can be directly on the other layer or substrate, or intervening layers may also be present.

It will be understood that the terms “connected to” or “coupled to” may include a physical and/or electrical connection or coupling.

The term “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as “not overlapping” or to “not overlap” another element, this may include that the elements are spaced apart from each other, offset from each other, or set aside from each other or any other suitable term as would be appreciated and understood by those of ordinary skill in the art.

The terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

“About” or “approximately” or “substantially” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

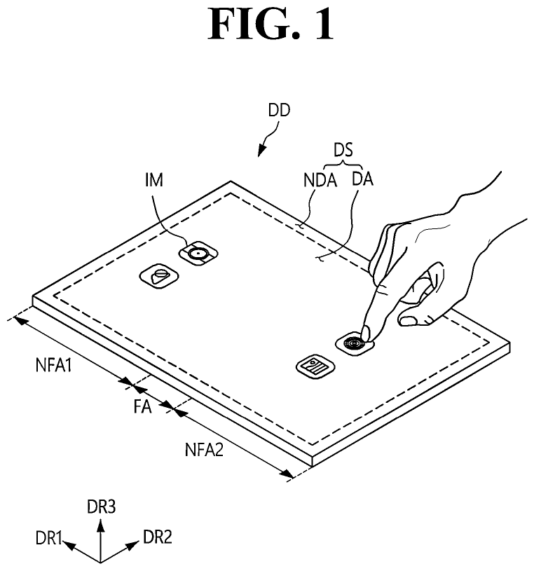

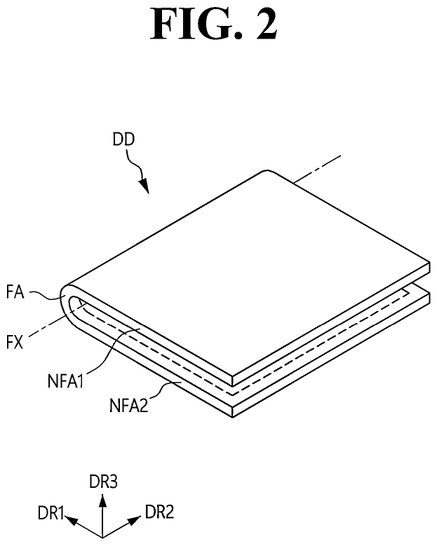

FIG. 1 is a schematic perspective view of a display device according to an embodiment in a first state. FIG. 2 is a schematic perspective view of the display device according to an embodiment in a second state. FIG. 1 illustrates a first state in which a display device DD is unfolded, and FIG. 2 illustrates a second state in which the display device DD is folded.

Referring to FIGS. 1 and 2, the display device DD according to an embodiment of the disclosure may have a rectangular shape having long sides in a first direction DR1 and having short sides in a second direction DR2 crossing the first direction DR1. However, the display device DD is not limited thereto, and may have various shapes such as a circular shape and/or a polygonal shape. The display device DD may be a flexible display device.

The first direction DR1 and the second direction DR2 may be horizontal directions, respectively, and cross each other. For example, the first direction DR1 and the second direction DR2 may be orthogonal to each other. In addition, a third direction DR3 may be a perpendicular direction crossing, for example, orthogonal to, the first direction DR1 and the second direction DR2. Unless otherwise defined, directions indicated by arrows of the first to third directions DR1, DR2, and DR3 may be referred to as a side, and directions opposite to the side may be referred to as another side. In addition, the terms “on”, “upper side”, “upper portion”, “top, and “upper surface” as used herein may refer to a direction toward which an arrow of the third direction DR3 is directed in the drawings, and the terms “below”, “lower side”, “lower portion”, “bottom, and “lower surface” used as herein may refer to a direction opposite to the direction toward which the arrow of the third direction DR3 is directed in the drawings.

The display device DD may include a folding area FA and multiple non-folding areas NFA1 and NFA2. The non-folding areas NFA1 and NFA2 may include a first non-folding area NFA1 and a second non-folding area NFA2. The folding area FA may be disposed between the first non-folding area NFA1 and the second non-folding area NFA2. The folding area FA, the first non-folding area NFA1, and the second non-folding area NFA2 may be arranged in the first direction DR1.

One folding area FA and two non-folding areas NFA1 and NFA2 have been illustrated as an example, but the numbers of folding areas FA and non-folding areas NFA1 and NFA2 are not limited thereto. For example, the display device DD may include multiple non-folding areas and multiple folding areas disposed between the non-folding areas.

An upper surface of the display device DD may be defined as a display surface DS and may have a plane defined by the first direction DR1 and the second direction DR2. Images IM generated by the display device DD may be provided to a user through the display surface DS.

The display surface DS may include a display area DA and non-display areas NDA around the display area DA. The display area DA may display an image, and the non-display areas NDA may not display an image. The non-display areas NDA may surround the display area DA and define edges of the display device DD printed in a predetermined or selected color.

As illustrated in FIGS. 1 and 2, the display device DD according to an embodiment may be a foldable display device DD that is folded or unfolded. For example, the display device DD may be folded by bending the folding area FA based on a folding axis FX parallel to the second direction DR2. The folding axis FX may be defined as a minor axis parallel to the short side of the display device DD.

As illustrated in FIGS. 1 and 2, in case that the display device DD is folded, the first non-folding area NFA1 and the second non-folding area NFA2 may face each other, and the display device DD may be in-folded so that the display surface DS is not exposed to the outside. However, the disclosure is not limited thereto, and the first non-folding area NFA1 and the second non-folding area NFA2 may face opposite directions, such that the display device DD may be out-folded so that the display surface DS is exposed to the outside. Hereinafter, for convenience of explanation, a case where the display device DD is in-folded will be described by way of example.

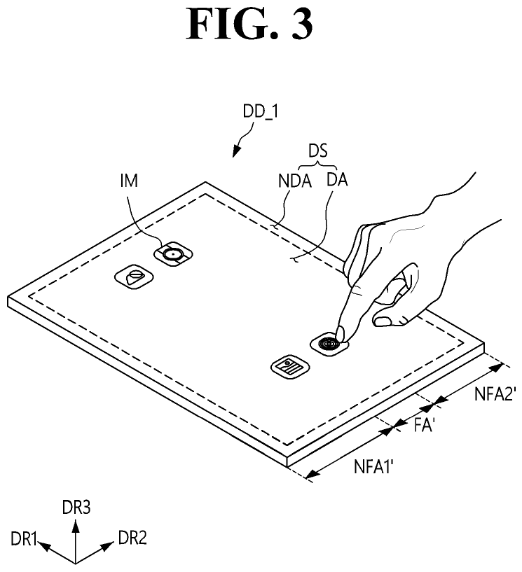

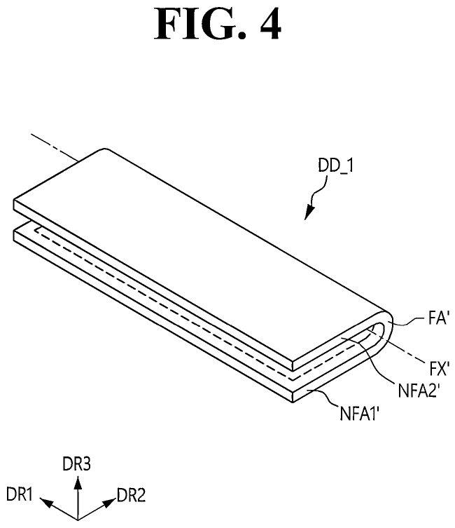

FIG. 3 is a schematic perspective view of a display device according to another embodiment in a first state. FIG. 4 is a schematic perspective view of the display device according to another embodiment in a second state. A display device DD_1 illustrated in FIGS. 3 and 4 may have substantially the same configuration as the display device DD illustrated in FIG. 1 except for a folding operation. Accordingly, a folding operation of the display device DD_1 will hereinafter be described.

Referring to FIGS. 3 and 4, the display device DD_1 may include a folding area FA′ and multiple non-folding areas NFA1′ and NFA2′. The non-folding areas NFA1′ and NFA2′ may include a first non-folding area NFA1′ and a second non-folding area NFA2′. The folding area FA′ may be disposed between the first non-folding area NFA1′ and the second non-folding area NFA2′. The folding area FA′, the first non-folding area NFA1′, and the second non-folding area NFA2′ may be arranged in the second direction DR2.

The display device DD_1 may be folded by bending the folding area FA′ based on a folding axis FX′ parallel to the first direction DR1. The folding axis FX′ may be defined as a major axis parallel to the long side of the display device DD_1. The display device DD illustrated in FIG. 1 may be folded based on the minor axis, while the display device DD_1 illustrated in FIG. 3 may be folded based on the major axis. The display device DD_1 may be in-folded so that the display surface DS is not exposed to the outside.

Hereinafter, for convenience of explanation, the display device DD in-folded based on the folding axis FX parallel to the minor axis will be described, but the disclosure is not limited thereto.

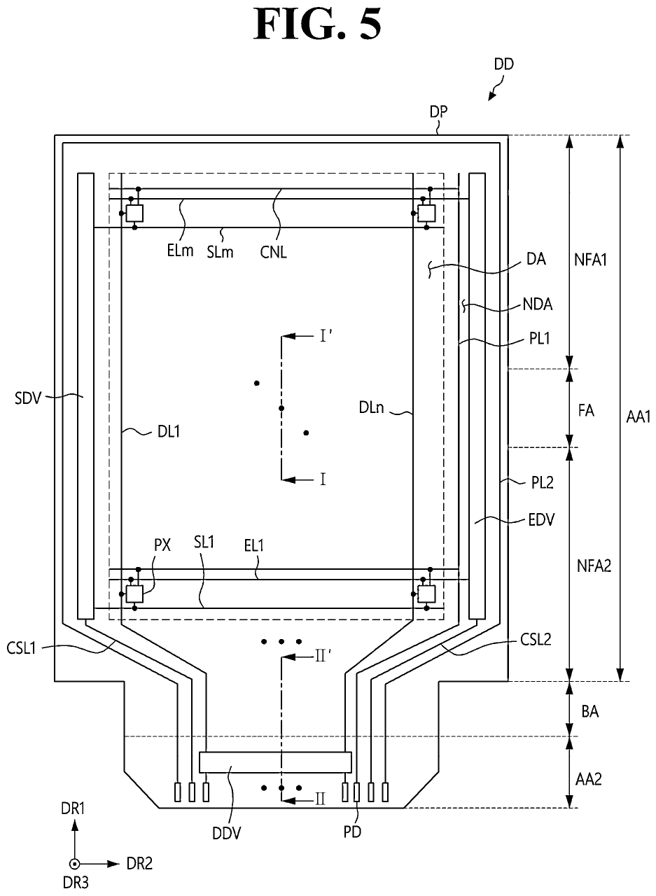

FIG. 5 is a schematic plan view of the display device according to an embodiment.

Referring to FIG. 5, the display device DD may include a display panel DP, a scan driver SDV, a data driver DDV, and an emission driver EDV.

The display panel DP according to an embodiment of the disclosure may be a light emitting display panel, and is not particularly limited. For example, the light emitting display panel may be an organic light emitting display panel or a quantum dot light emitting display panel. A light emitting layer of the organic light emitting display panel may include an organic light emitting material. A light emitting layer of the quantum dot light emitting display panel may include quantum dots, quantum rods, and the like. Hereinafter, it will be described that the display panel DP is an organic light emitting display panel.

The display panel DP may be a flexible display panel. For example, the display panel DP may include multiple electronic elements disposed on a flexible substrate. The display panel DP may extend to be more elongated in the first direction DR1 than in the second direction DR2. The display panel DP may have a plane defined by the first and second directions DR1 and DR2.

The display panel DP may include a first area AA1, a second area AA2, and a bending area BA disposed between the first area AA1 and the second area AA2. The bending area BA may extend in the second direction DR2, and the first area AA1, the bending area BA, and the second area AA2 may be arranged in the first direction DR1.

The first area AA1 may have long sides extending in the first direction DR1 and facing each other in the second direction DR2. The first area AA1 may have short sides extending in the second direction DR2 and facing each other in the first direction DR1. Based on the second direction DR2, a length of the first area AA1 may be greater than lengths of the bending area BA and the second area AA2.

The first area AA1 may include a display area DA and non-display areas NDA around the display area DA. The non-display areas NDA may surround the display area DA. The display area DA may be an area that displays an image, and the non-display areas NDA may be areas that do not display an image. The second area AA2 and the bending area BA may be areas that do not display an image.

The first area AA1 may include a first non-folding area NFA1, a second non-folding area NFA2, and a folding area FA between the first non-folding area NFA1 and the second non-folding area NFA2 when viewed in the second direction DR2.

The display panel DP may include multiple pixels PX, multiple scan lines SL1 to SLm, multiple data lines DL1 to DLn, multiple emission lines EL1 to ELm, first and second control lines CSL1 and CSL2, a first power line PL1, a second power line PL2, connection lines CNL, and multiple pads PD, where m and n are natural numbers. The pixels PX may be disposed in the display area DA and may be connected to the scan lines SL1 to SLm, the data lines DL1 to DLn, and the emission lines EL1 to ELm.

The scan driver SDV and the emission driver EDV may be disposed in the non-display areas NDA. The scan driver SDV and the emission driver EDV may be disposed in the non-display areas NDA adjacent to the long sides of the first area AA1, respectively. The data driver DDV may be disposed in the second area AA2. The data driver DDV may be manufactured in the form of an integrated circuit chip and mounted on the second area AA2.

The scan lines SL1 to SLm may extend in the second direction DR2 and be connected to the scan driver SDV. The data lines DL1 to DLn may extend in the first direction DR1, and may be connected to the data driver DDV via the bending area BA. The emission lines EL1 to ELm may extend in the second direction DR2 and be connected to the emission driver EDV.

The first power line PL1 may extend in the first direction DR1 and be disposed in the non-display area NDA. The first power line PL1 may be disposed between the display area DA and the emission driver EDV. However, the first power line PL1 is not limited thereto, and may also be disposed between the display area DA and the scan driver SDV.

The first power line PL1 may extend to the second area AA2 via the bending area BA. The first power line PL1 may extend toward a lower end of the second area AA2 in plan view. The first power line PL1 may receive a first voltage.

The second power line PL2 may be disposed in the non-display areas NDA adjacent to the long sides of the first area AA1 and the non-display area NDA facing the second area AA2 with the display area DA interposed therebetween. The second power line PL2 may be disposed outside the scan driver SDV and the emission driver EDV.

The second power line PL2 may extend to the second area AA2 via the bending area BA. The second power line PL2 may extend in the first direction DR1 with the data driver DDV interposed therebetween in the second area AA2. The second power line PL2 may extend toward the lower end of the second area AA2 in plan view.

The second power line PL2 may receive a second voltage having a lower level than the first voltage. For convenience of explanation, a connection relationship has not been illustrated, but the second power line PL2 may extend to the display area DA and be connected to the pixels PX, and the second voltage may be provided to the pixels PX through the second power line PL2.

The connection lines CNL may extend in the second direction DR2 and may be arranged in the first direction DR1. The connection lines CNL may be connected to the first power line PL1 and the pixels PX. The first voltage may be applied to the pixels PX through the first power line PL1 and the connection lines CNL connected to each other.

The first control line CSL1 may be connected to the scan driver SDV and may extend toward the lower end of the second area AA2 via the bending area BA. The second control line CSL2 may be connected to the emission driver EDV and may extend toward the lower end of the second area AA2 via the bending area BA. The data driver DDV may be disposed between the first control line CSL1 and the second control line CSL2.

In plan view, the pads PD may be disposed adjacent to the lower end of the second area AA2. The data driver DDV, the first power line PL1, the second power line PL2, the first control line CSL1, and the second control line CSL2 may be connected to the pads PD.

The data lines DL1 to DLn may be connected to corresponding pads PD through the data driver DDV. For example, the data lines DL1 to DLn may be connected to the data driver DDV, and the data driver DDV may be connected to the pads PD each corresponding to the data lines DL1 to DLn.

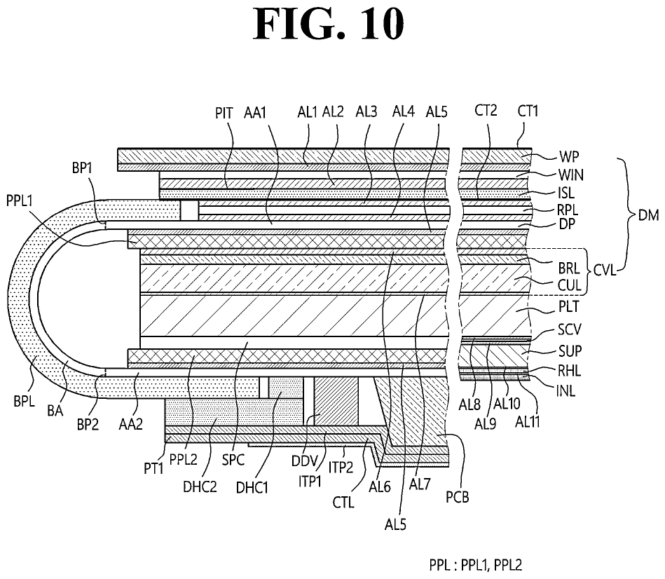

Although not illustrated in FIG. 5, the display device DD may include a printed circuit board PCB (see FIG. 10) connected to the pads PD and a timing controller disposed on the printed circuit board PCB (see FIG. 10). The timing controller may be manufactured as an integrated circuit chip and mounted on the printed circuit board. The timing controller may be connected to the pads PD through the printed circuit board.

The timing controller may control operations of the scan driver SDV, the data driver DDV, and the emission driver EDV. The timing controller may generate a scan control signal, a data control signal, and an emission control signal in response to control signals received from the outside.

The scan control signal may be provided to the scan driver SDV through the first control line CSL1. The emission control signal may be provided to the emission driver EDV through the second control line CSL2. The data control signal may be provided to the data driver DDV. The timing controller may receive image signals from the outside, convert data formats of the image signals so as to meet interface specifications with the data driver DDV, and provide the image signals of which the data formats are converted to the data driver DDV.

The scan driver SDV may generate multiple scan signals in response to the scan control signal. The scan signals may be applied to the pixels PX through the scan lines SL1 to SLm. The scan signals may be sequentially applied to the pixels PX.

The data driver DDV may generate multiple data voltages corresponding to the image signals in response to the data control signal. The data voltages may be applied to the pixels PX through the data lines DL1 to DLn. The emission driver EDV may generate multiple emission signals in response to the emission control signal. The emission signals may be applied to the pixels PX through the emission lines EL1 to ELm.

The pixels PX may receive the data voltages in response to the scan signals. The pixels PX may display an image by emitting light having a luminance corresponding to the data voltages in response to the emission signals. An emission time of the pixels PX may be controlled by the emission signals.

Each of the pixels PX may include a self-light emitting element. In an embodiment, the self-light emitting element may include at least one of an organic light emitting diode, a quantum dot light emitting diode, an inorganic material-based micro light emitting diode (e.g., a micro LED), and an inorganic material-based nano light emitting diode (e.g., a nano LED). Hereinafter, for convenience of explanation, a case where the self-light emitting element is an organic light emitting diode will be described by way of example.

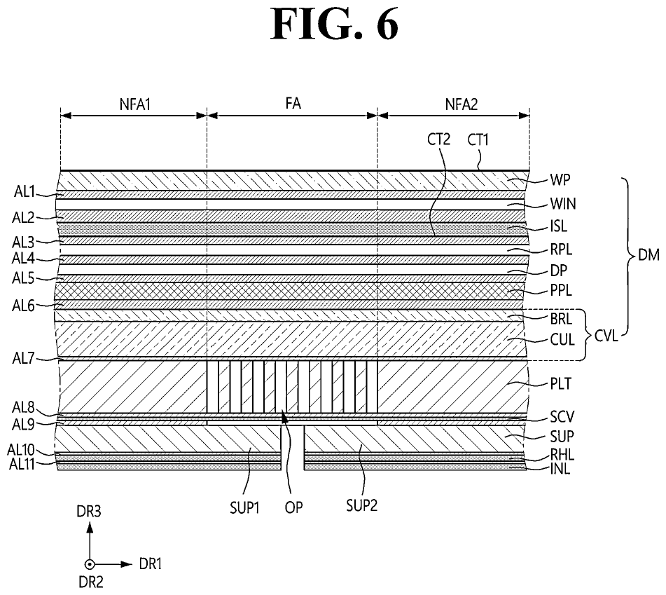

FIG. 6 is a schematic cross-sectional view taken along I-I′ of FIG. 5. FIG. 6 is a cross-sectional view of the display device DD appearing in a portion of the first area AA1 (see FIG. 5) of FIG. 5.

Referring to FIG. 6, the display device DD may include a display panel DP, an anti-reflection layer RPL, an impact absorption layer ISL, a window WIN, a window protection layer WP, a first coating layer CT1, a second coating layer CT2, a panel protection layer PPL (e.g., a panel protection member), a cover layer CVL (e.g., a panel lower member), a plate PLT (e.g., a panel support member), a sub-cover layer SCV, a support part SUP, a heat dissipation layer RHL, an insulating layer INL, and first to eleventh adhesive layers AL1 to AL11. The cover layer CVL and members disposed above the cover layer CVL may be defined as a display module DM.

The anti-reflection layer RPL, the impact absorption layer ISL, the window WIN, the window protection layer WP, the first coating layer CT1, and the second coating layer CT2 may be disposed on the display panel DP. The panel protection layer PPL, the cover layer CVL, the plate PLT, the sub-cover layer SCV, the support part SUP, the heat dissipation layer RHL, and the insulating layer INL may be disposed below the display panel DP.

The anti-reflection layer RPL may be disposed on a surface, for example, an upper surface, of the display panel DP. The anti-reflection layer RPL may be defined as an external light anti-reflection film. The anti-reflection layer RPL may decrease reflectivity of external light incident from an upper portion of the display device DD toward the display panel DP. As an example, the anti-reflection layer RPL may include a phase retarder and/or a polarizer.

The impact absorption layer ISL may be disposed on the anti-reflection layer RPL. The impact absorption layer ISL may absorb external impact applied from the upper portion of the display device DD toward the display panel DP to protect the display panel DP. The impact absorption layer ISL may be manufactured in the form of a stretched film.

The impact absorption layer ISL may include a flexible plastic material. The flexible plastic material may be defined as a synthetic resin film. For example, the impact absorption layer ISL may include a flexible plastic material such as polyimide (PI) and/or polyethylene terephthalate (PET). The impact absorption layer ISL may have an elastic modulus of 1 GPa or more. In some embodiments, the impact absorption layer ISL may be omitted.

The window WIN may be disposed on the impact absorption layer ISL. The window WIN may protect the display panel DP and the anti-reflection layer RPL from an external scratch. The window WIN may have an optically clear property.

In some embodiments, the window WIN may include glass. The window WIN may be defined as ultra thin glass (UTG). However, the window WIN is not limited thereto, and may include a synthetic resin film.

The window WIN may have a multilayer structure or a single layer structure. For example, the window WIN may include multiple synthetic resin films bonded to each other with an adhesive or may include a glass substrate and a synthetic resin film bonded to each other with an adhesive.

The window protection layer WP may be disposed on the window WIN. The first coating layer CT1 may be coated on an upper surface of the window protection layer WP. The window protection layer WP and the first coating layer CT1 may protect the window WIN. The window protection layer WP may include a film having an elastic modulus of 15 GPa or less at room temperature.

In some embodiments, the window protection layer WP may include a flexible plastic material such as polyimide and/or polyethylene terephthalate. The first coating layer CT1 may include a hard coating layer. However, the first coating layer CT1 is not limited thereto, and may further include an anti-fingerprint layer or an anti-scattering layer defined as a functional layer.

The second coating layer CT2 may be disposed between the anti-reflection layer RPL and the impact absorption layer ISL. The second coating layer CT2 may include a hard coating layer. The second coating layer CT2 may planarize a lower surface of the impact absorption layer ISL that may have a curved surface.

The first adhesive layer AL1 may be disposed between the window protection layer WP and the window WIN. The window protection layer WP and the window WIN may be bonded to each other by the first adhesive layer AL1.

The second adhesive layer AL2 may be disposed between the window WIN and the impact absorption layer ISL. The window WIN and the impact absorption layer ISL may be bonded to each other by the second adhesive layer AL2.

The third adhesive layer AL3 may be disposed between the impact absorption layer ISL and the anti-reflection layer RPL. The impact absorption layer ISL and the anti-reflection layer RPL may be bonded to each other by the third adhesive layer AL3. In case that the second coating layer CT2 is disposed on the lower surface of the impact absorption layer ISL, the third adhesive layer AL3 may be substantially adhered to the second coating layer CT2 and the anti-reflection layer RPL.

The fourth adhesive layer AL4 may be disposed between the anti-reflection layer RPL and the display panel DP. The anti-reflection layer RPL and the display panel DP may be bonded to each other by the fourth adhesive layer AL4.

The first to fourth adhesive layers AL1 to AL4 may include a transparent adhesive such as a pressure sensitive adhesive (PSA) and/or an optically clear adhesive (OCA).

The panel protection layer PPL (e.g., the panel protection member) may be disposed on another surface, for example, a lower surface, of the display panel DP. The panel protection layer PPL may protect a lower portion of the display panel DP. The panel protection layer PPL may include a flexible plastic material. For example, the panel protection layer PPL may include polyethylene terephthalate (PET).

The cover layer CVL (e.g., the panel lower member) may be disposed on another surface, for example, a lower surface, of the panel protection layer PPL. The cover layer CVL may define a lower portion of the display module DM. The cover layer CVL may absorb external impact applied to the lower portion of the display module DM. The cover layer CVL may include a barrier layer BRL and a cushion layer CUL. The sixth adhesive layer AL6 and the seventh adhesive layer AL7 may be defined as components of the cover layer CVL.

The barrier layer BRL may be disposed on another surface, for example, the lower surface, of the panel protection layer PPL. The barrier layer BRL may increase resistance to a compressive force caused by external pressure. Accordingly, the barrier layer BRL may serve to prevent deformation of the display panel DP. The barrier layer BRL may include a flexible plastic material such as polyimide and/or polyethylene terephthalate.

The cushion layer CUL may be disposed on another surface, for example, a lower surface, of the barrier layer BRL. The cushion layer CUL may absorb external impact applied to the lower portion of the display module DM to protect the display panel DP. The cushion layer CUL may include a foam sheet having a predetermined or selected elasticity. The cushion layer CUL may include foam, sponge, polyurethane, and/or thermoplastic polyurethane. The cushion layer CUL may be directly formed on the lower surface of the barrier layer BRL using the barrier layer BRL as a base layer.

At least one of the barrier layer BRL and the cushion layer CUL may have a color absorbing light. For example, at least one of the barrier layer BRL and the cushion layer CUL may have a black color. Components disposed below the cover layer CVL may not be viewed when the display device DD is viewed from above the display device DD. In another embodiment, the cover layer CVL may further include a separate light blocking layer.

The plate PLT (e.g., the panel support member) may be disposed on another surface, for example, a lower surface, of the cover layer CVL. For example, the plate PLT may be disposed on another surface, for example, a lower surface, of the cushion layer CUL.

The plate PLT may include a material having an elastic modulus of about 60 GPa or more. The plate PLT may include a metal material such as stainless steel. For example, the plate PLT may include SUS 304, but is not limited thereto, and may include various metal materials. The plate PLT may support the display module DM. Heat dissipation performance of the display device DD may be improved by the plate PLT.

In plan view, multiple openings OP may be defined in a portion of the plate PLT overlapping the folding area FA, approximately, at the center of the folding area FA. The portion of the plate PLT overlapping the folding area FA may be readily deformed by the openings OP.

The fifth adhesive layer AL5 may be disposed between the display panel DP and the panel protection layer PPL. The display panel DP and the panel protection layer PPL may be bonded to each other by the fifth adhesive layer AL5.

The sixth adhesive layer AL6 may be disposed between the panel protection layer PPL and the barrier layer BRL. The panel protection layer PPL and the barrier layer BRL may be bonded to each other by the sixth adhesive layer AL6.

The seventh adhesive layer AL7 may be disposed between the cushion layer CUL and the plate PLT. The cushion layer CUL and the plate PLT may be bonded to each other by the seventh adhesive layer AL7.

The fifth to seventh adhesive layers AL5 to AL7 may include a transparent adhesive such as a pressure sensitive adhesive and/or an optically clear adhesive.

The sub-cover layer SCV may be disposed on another surface, for example, a lower surface, of the plate PLT. The sub-cover layer SCV may cover the openings OP defined in the plate PLT. The sub-cover layer SCV may have a lower elastic modulus than the plate PLT. For example, the sub-cover layer SCV may include thermoplastic polyurethane or rubber, but is not limited thereto. The sub-cover layer SCV may be manufactured in the form of a sheet and attached to the plate PLT. The sub-cover layer SCV may prevent foreign substances from permeating into the openings OP defined in the plate PLT.

The eighth adhesive layer AL8 may be disposed between the sub-cover layer SCV and the plate PLT. The sub-cover layer SCV and the plate PLT may be bonded to each other by the eighth adhesive layer AL8.

The support part SUP may be disposed on another surface, for example, a lower surface, of the sub-cover layer SCV. The support part SUP may support the first non-folding area NFA1 and the second non-folding area NFA2 of the display module DM. The support part SUP may include a metal. For example, the support part SUP may include a copper alloy. However, this is only an example, and the support part SUP may include various metals (e.g., Invar or stainless steel).

The support part SUP may include a first support part SUP1 and a second support part SUP2 arranged in the first direction DR1. The first support part SUP1 may overlap the first non-folding area NFA1 and support the first non-folding area NFA1. The second support part SUP2 may overlap the second non-folding area NFA2 and support the second non-folding area NFA2. The first support part SUP1 and the second support part SUP2 may extend to the folding area FA to overlap portions of the folding area FA in the third direction DR3, but may be spaced apart from each other in the folding area FA.

The first support part SUP1 and the second support part SUP2 may be disposed adjacent to each other in the folding area FA. The first support part SUP1 and the second support part SUP2 may support the portion of the plate PLT in which the openings OP are defined in the folding area FA. Accordingly, in case that a pressure is applied from above to the portion of the plate PLT in which the openings OP are defined, deformation of the portion of the plate PLT in which the openings OP are defined may be prevented by the support part SUP. The support part SUP may prevent shapes of components disposed above the support part SUP from being changed by components disposed below the support part SUP.

The ninth adhesive layer AL9 may be disposed between the support part SUP and the sub-cover layer SCV. The support part SUP and the sub-cover layer SCV may be bonded to each other by the ninth adhesive layer AL9. The ninth adhesive layer AL9 may be disposed in an area overlapping the first non-folding area NFA1 and an area overlapping the second non-folding area NFA2. The ninth adhesive layer AL9 may not be disposed on a portion of the first support part SUP1 overlapping the folding area FA and a portion of the second support part SUP2 overlapping the folding area FA.

The heat dissipation layer RHL may be disposed on another surface, for example, a lower surface of the support part SUP. The heat dissipation layer RHL may be a thermally conductive sheet having high thermal conductivity. The heat dissipation layer RHL may have a heat dissipation function.

The tenth adhesive layer AL10 may be disposed between the heat dissipation layer RHL and the support part SUP. The tenth adhesive layer AL10 may be disposed between the first support part SUP1 and the heat dissipation layer RHL and between the second support part SUP2 and the heat dissipation layer RHL. The heat dissipation layer RHL and the support part SUP may be bonded to each other by the tenth adhesive layer AL10.

The insulating layer INL may be disposed on another surface, for example, a lower surface of the heat dissipation layer RHL.

The eleventh adhesive layer AL11 may be disposed between the insulating layer INL and the heat dissipation layer RHL. The insulating layer INL and the heat dissipation layer RHL may be bonded to each other by the eleventh adhesive layer AL11.

The eighth to eleventh adhesive layers AL8 to AL11 may include a transparent adhesive such as a pressure sensitive adhesive and/or an optically clear adhesive.

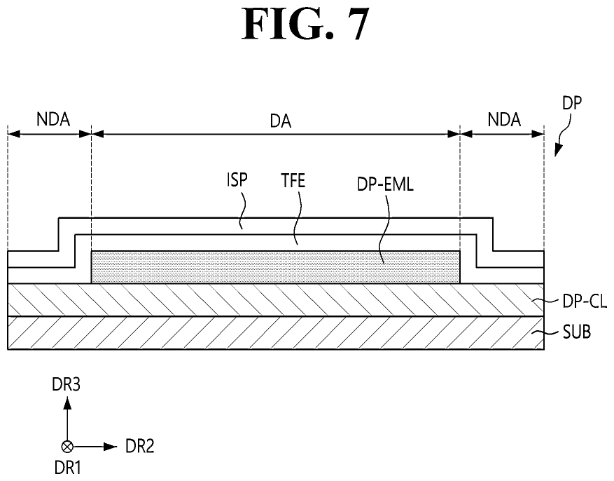

FIG. 7 is a schematic cross-sectional view of a display panel according to an embodiment. A cross section of the display panel viewed in the first direction DR1 has been illustrated as an example in FIG. 7, and an illustrative structure of the display panel has been illustrated in FIG. 7.

Referring to FIG. 7, the display panel DP may include a substrate SUB, a circuit element layer DP-CL disposed on the substrate SUB, a display element layer DP-EML disposed on the circuit element layer DP-CL, a thin film encapsulation layer TFE disposed on the display element layer DP-EML, and an input sensing unit ISP disposed on the thin film encapsulation layer TFE. The display element layer DP-EML may be disposed on a display area DA.

The substrate SUB may include a display area DA and a non-display area NDA around the display area DA. The substrate SUB may include a flexible plastic material. For example, the substrate SUB may include polyimide (PI).

The circuit element layer DP-CL may include an insulating layer, semiconductor patterns, conductive patterns, signal lines, and the like. An insulating layer, a semiconductor layer, and a conductive layer may be formed on the substrate SUB by methods such as coating and deposition. Thereafter, the insulating layer, the semiconductor layer, and the conductive layer may be selectively patterned through multiple photolithography processes, such that the semiconductor patterns, the conductive patterns, and the signal lines may be formed.

The circuit element layer DP-CL may include transistors formed as the semiconductor patterns, the conductive patterns, and the signal lines. The display element layer DP-EML may include light emitting elements connected to the transistors. The pixels PX may include transistors and light emitting elements.

The thin film encapsulation layer TFE may be disposed on the circuit element layer DP-CL so as to cover the display element layer DP-EML. The thin film encapsulation layer TFE may include an inorganic layer, an organic layer, and an inorganic layer that are stacked on each other. The inorganic layers may include an inorganic material and may protect the pixels from moisture/oxygen. The organic layer may include an organic material and may protect the pixels PX from foreign substances such as dust particles.

The input sensing unit ISP may include multiple sensors (not illustrated) for sensing an external input. The sensors may sense the external input in a capacitive manner. The external input may include various types of inputs such as a portion of a user's body, light, heat, a pen, and/or a pressure.

The input sensing unit ISP may be directly manufactured on the thin film encapsulation layer TFE in manufacturing the display panel DP. However, the input sensing unit ISP is not limited thereto, and may also be manufactured as a panel separate from the display panel DP and attached to the display panel DP by an adhesive layer.

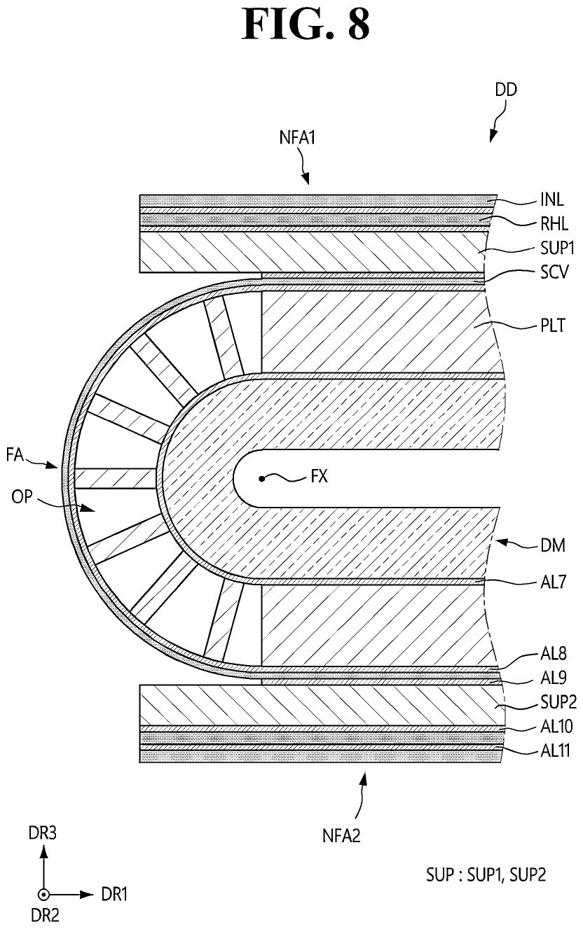

FIG. 8 is a schematic cross-sectional view of the display device according to an embodiment in the second state. FIG. 8 illustrates a cross-sectional view of the display device according to an embodiment in a folded state. As an example, detailed components of the display module DM are not illustrated in FIG. 8.

Referring to FIG. 8, the display device DD may be in-folded around the folding axis FX. The folding area FA may be bent, such that the first non-folding area NFA1 and the second non-folding area NFA2 may face each other. The first non-folding area NFA1 overlapping the first support part SUP1 and the second non-folding area NFA2 overlapping the second support part SUP2 may be maintained in a flat state.

The display device DD may be changed from the first state in which it is flat as illustrated in FIG. 6 to the second state in which it is folded as illustrated in FIG. 8 or be changed from the second state to the first state. Such a folding operation may be repeatedly performed.

Since the display module DM is a flexible display module, the folding area FA of the display module DM may be readily bent. However, since the first and second support parts SUP1 and SUP2 are in a rigid type, they may not bend.

If the ninth adhesive layer AL9 is disposed up to the folding area FA, the first and second support parts SUP1 and SUP2 may be attached to the sub-cover layer SCV in the folding area FA. For example, the first and second support parts SUP1 and SUP2 may be attached to the folding area FA of the display module DM through the ninth adhesive layer AL9, the eighth adhesive layer AL8, and the seventh adhesive layer AL7.

If the first and second support parts SUP1 and SUP2 are attached to the folding area FA of the display module DM, the folding area FA may not be bent well because of the first and second support parts SUP1 and SUP2 in the rigid type. Accordingly, a folding operation of the display module DM may be difficult.

As illustrated in FIG. 8, the ninth adhesive layer AL9 may not be disposed in an area overlapping the folding area FA. Accordingly, portions of the first and second support parts SUP1 and SUP2 overlapping the folding area FA may not be attached to the display module DM, and thus, the folding area FA may be readily bent.

The openings OP overlapping the folding area FA may be defined in the plate PLT. Accordingly, during a folding operation, the portion of the plate PLT overlapping the folding area FA may be readily bent by the openings OP.

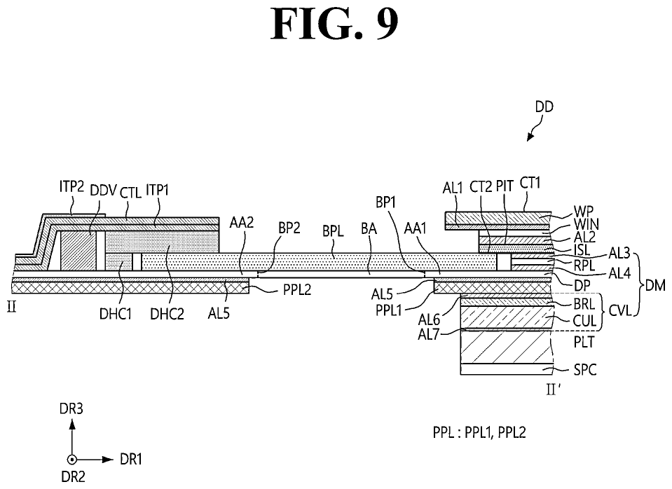

FIG. 9 is a schematic cross-sectional view taken along line II-II′ of FIG. 5. FIG. 10 is a schematic cross-sectional view illustrating a state in which the display device illustrated in FIG. 9 is bent.

Referring to FIGS. 9 and 10, the bending area BA may be bent to be convex toward the outside of the display panel DP. The bending area BA may be bent to have a predetermined or selected curvature. For example, the bending area BA may be bent from a first boundary BP1, which is a boundary between the bending area BA and the first area AA1, to a second boundary BP2, which is a boundary between the bending area BA and the second area AA2.

As illustrated in FIG. 10, in the state in which the display device is bent, the anti-reflection layer RPL, the impact absorption layer ISL, the window WIN, the window protection layer WP, the first coating layer CT1, and the second coating layer CT2 may be disposed on the first area AA1. The panel protection layer PPL, the cover layer CVL, and the plate PLT may be disposed below the first area AA1. The panel protection layer PPL, the cover layer CVL, and the plate PLT may be disposed between the first area AA1 and the second area AA2.

The display device DD may further include a printed layer PIT and a spacer SPC that overlap the first area AA1 in the third direction DR3. The display device DD may further include a bending protection layer BPL that overlaps the bending area BA in the third direction DR3. The display device DD may further include a data driver DDV, a first step compensation layer DHC1, a second step compensation layer DHC2, a first insulating tape ITP1, a second insulating tape ITP2, a conductive layer CTL, and a printed circuit board PCB that overlap the second area AA2 in the third direction DR3.

The printed layer PIT may be disposed on a surface, for example, an upper surface, of the impact absorption layer ISL. For example, the printed layer PIT may be disposed between the second adhesive layer AL2 and the impact absorption layer ISL. The printed layer PIT may be disposed adjacent to an end of the impact absorption layer ISL adjacent to the bending area BA. The printed layer PIT may extend along the first direction DR1 to overlap the first area AA1 and the non-display area. The printed layer PIT may include a black color, but is not limited thereto, and may include various colors.

The spacer SPC may be disposed on another surface, for example, the lower surface, of the plate PLT. For example, in the state in which the display device DD is bent as illustrated in FIG. 10, the spacer SPC may be disposed between the plate PLT and a second panel protection layer PPL2 to be described later. The spacer SPC may be disposed to overlap the first area AA1. The spacer SPC may be disposed in a portion of the first area AA1 adjacent to the bending area BA based on the first direction DR1.

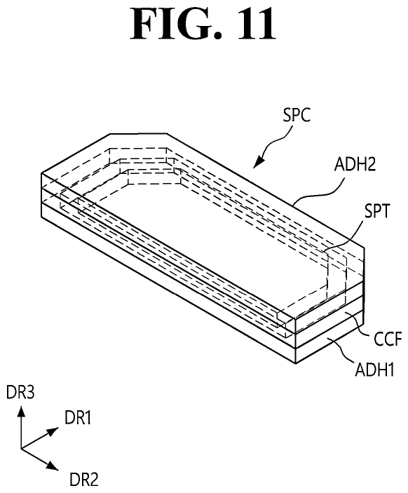

The spacer SPC may be in the form of a double-sided tape. For example, the spacer SPC may include a support layer and adhesives disposed on an upper surface and a lower surface of the support layer. The spacer SPC may serve to compensate for a gap between the second area AA2 and the plate PLT in case that the display device DD is bent. The spacer SPC will be described later in detail with reference to FIG. 11.

The bending protection layer BPL may be disposed to overlap the bending area BA in the third direction DR3 in a state before the display device is bent as illustrated in FIG. 9. The bending protection layer BPL may be disposed on the bending area BA, a portion of the first area AA1 adjacent to the bending area BA, and a portion of the second area AA2 adjacent to the bending area BA. The bending protection layer BPL may continuously extend from a portion of the first area AA1 adjacent to the bending area BA to the bending area BA and a portion of the second area AA2 adjacent to the bending area BA.

The bending protection layer BPL may be spaced apart from the anti-reflection layer RPL in the first direction DR1 and be disposed between the impact absorption layer ISL and the first area AA1 of the display panel DP in the third direction DR3. The bending protection layer BPL may be spaced apart from the data driver DDV in the first direction DR1 and be disposed on the second area AA2 of the display panel DP.

The bending protection layer BPL may include an acrylic resin and/or a urethane-based resin. The bending protection layer BPL may be bent together with the bending area BA. The bending protection layer BPL may serve to protect the bending area BA. The bending protection layer BPL may cover lines disposed in the bending area BA to protect the lines disposed in the bending area BA. The bending protection layer BPL may supplement rigidity of the bending area BA to prevent a crack of the bending area BA in case that the bending area BA is bent. The bending protection layer BPL may protect the bending area BA from external impact.

The panel protection layer PPL (e.g., the panel protection member) may be disposed to overlap the first area AA1 and the second area AA2, but may not overlap the bending area BA. The panel protection layer PPL may include a first panel protection layer PPL1 (e.g., a first panel protection member) disposed below the first area AA1 and a second panel protection layer PPL2 (e.g., a second panel protection member) disposed below the second area AA2, in the state before the display device is bent as illustrated in FIG. 9. In the state in which the display device is bent as illustrated in FIG. 10, the second panel protection layer PPL2 may be disposed below the first area AA1 and the first panel protection layer PPL1 together with the second area AA2. Since the panel protection layer PPL is not disposed in the bending area BA, the bending area BA may be more readily bent.

The data driver DDV may be disposed on the second area AA2 of the display panel DP in the state before the display device is bent as illustrated in FIG. 9. The data driver DDV may be defined as a driving integrated circuit (IC). The data driver DDV may be disposed below the first area AA1 together with the second area AA2 in the state in which the display device is bent as illustrated in FIG. 10. Since the second area AA2 is disposed below the first area AA1, the data driver DDV may be disposed below the second area AA2.

Hereinafter, for convenience of explanation, components of the display device DD will be described based on a bending structure illustrated in FIG. 10.

The first step compensation layer DHC1 may be spaced apart from an end of the bending protection layer BPL disposed below the second area AA2. The first step compensation layer DHC1 may be disposed below the second area AA2 between the bending protection layer BPL and the data driver DDV.

The second step compensation layer DHC2 may be disposed below the first step compensation layer DHC1 and extend toward a lower portion of the bending protection layer BPL adjacent to the first step compensation layer DHC1. For example, the second step compensation layer DHC2 may overlap the first step compensation layer DHC1 and the bending protection layer BPL in the third direction DR3. The second step compensation layer DHC2 may be spaced apart from the second boundary BP2 by a predetermined or selected distance based on the first direction DR1.

Each of the first step compensation layer DHC1 and the second step compensation layer DHC2 may be defined as a double-sided tape. For example, each of the first step compensation layer DHC1 and the second step compensation layer DHC2 may include a base layer made of polyethylene terephthalate having flexibility and adhesives disposed on an upper surface and a lower surface of the base layer. The adhesive may include an acrylic adhesive. However, materials of the base layer and the adhesive are not limited thereto. In the second area AA2, a step formed by the bending protection layer BPL and the data driver DDV may be compensated for by the first step compensation layer DHC1 and the second step compensation layer DHC2.

The first insulating tape ITP1 may be disposed below the second step compensation layer DHC2 and extend toward a lower portion of the data driver DDV. For example, the first insulating tape ITP1 may be disposed below the second step compensation layer DHC2 and the data driver DDV and may overlap the second step compensation layer DHC2 and the data driver DDV in the third direction DR3. The first insulating tape ITP1 may be disposed below the second area AA2 so as to cover the data driver DDV. The first insulating tape ITP1 may include a base layer including an insulating material and having flexibility and adhesives disposed on an upper surface and a lower surface of the base layer.

The conductive layer CTL may be disposed below the first insulating tape ITP1. The conductive layer CTL may include a conductive material. The conductive layer CTL may be defined as an antistatic layer.

The second insulating tape ITP2 may be disposed below the conductive layer CTL. The second insulating tape ITP2 may include a base layer including an insulating material and having flexibility and an adhesive disposed on an upper surface of the base layer. The second insulating tape ITP2 may include a coating layer disposed on a lower surface of the base layer. Since an adhesive is not disposed on the lower surface of the base layer of the second insulating tape ITP2, the second insulating tape ITP2 may not be attached to a case in the event that the display device DD is accommodated in the case.

The second insulating tape ITP2 may not be disposed on a first portion PTI adjacent to a side of the conductive layer CTL. A side of the conductive layer CTL may be a side adjacent to the second boundary BP2. For example, the first portion PTI adjacent to the second boundary BP2 may be exposed to the outside.

The printed circuit board PCB may be spaced apart from the data driver DDV and be disposed below the second area AA2. The first insulating tape ITP1, the second insulating tape IPT2, and the conductive layer CTL may extend toward the printed circuit board PCB and be disposed below the printed circuit board PCB.

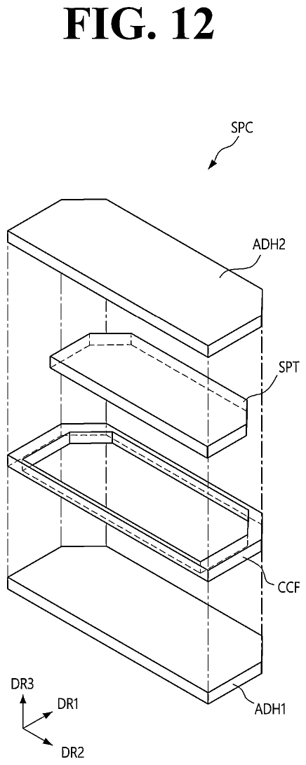

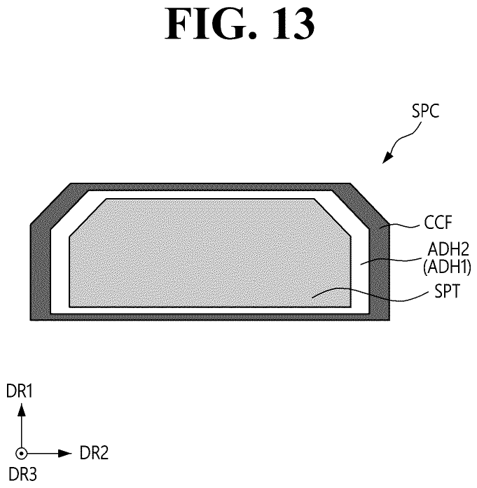

FIG. 11 is a schematic perspective view of a spacer according to an embodiment. FIG. 12 is an exploded schematic perspective view of the spacer according to an embodiment. FIG. 13 is a schematic plan view of the spacer according to an embodiment.

Referring to FIGS. 11 to 13, the spacer SPC may include a first attachment layer ADH1, a support layer SPT and an outer peripheral film CCF disposed on the first attachment layer ADH1, and a second attachment layer ADH2 disposed on the support layer SPT and the outer peripheral film CCF.

The first attachment layer ADH1 may include a material having adhesiveness. For example, the first attachment layer ADH1 may be defined as an adhesive. For example, the first attachment layer ADH1 may include a transparent adhesive such as a pressure sensitive adhesive (PSA) and/or an optically clear adhesive (OCA). The first attachment layer ADH1 may include an acrylic adhesive. In some embodiments, the first attachment layer ADH1 may be a transparent layer.

The support layer SPT may be disposed on the first attachment layer ADH1. The support layer SPT may be disposed approximately at the center of the first attachment layer ADH1, but is not limited thereto. The support layer SPT may be disposed between the first attachment layer ADH1 and the second attachment layer ADH2 to support the first attachment layer ADH1 and the second attachment layer ADH2. The support layer SPT may support members disposed above and below the spacer SPC by having considerable hardness. For example, the hardness of the support layer SPT may be greater than hardness of the first attachment layer ADH1, the outer peripheral film CCF, and the second attachment layer ADH2. In an embodiment, the support layer SPT may include a material having flexibility such as polyethylene terephthalate (PET). In another embodiment, the support layer SPT may include a stainless steel metal such as SUS or STS for impact absorption and protection functions.

The outer peripheral film CCF may be disposed on the first attachment layer ADH1 and may be disposed along an outer edge of the first attachment layer ADH1. The outer peripheral film CCF may be disposed at the same layer as the support layer SPT. A height of the outer peripheral film CCF may be substantially the same as a height of the support layer SPT. The outer peripheral film CCF may surround the support layer SPT. The outer peripheral film CCF may be spaced apart from the support layer SPT by a predetermined or selected distance in the first direction DR1 and the second direction DR2. The distance may be within about 0.5 mm.

The outer peripheral film CCF may include a material having adhesiveness like the first attachment layer ADH1. For example, the outer peripheral film CCF may be defined as an adhesive. For example, the outer peripheral film CCF may include a transparent adhesive such as a pressure sensitive adhesive (PSA) and/or an optically clear adhesive (OCA). The outer peripheral film CCF may include an acrylic adhesive.

In an embodiment, the outer peripheral film CCF may include an opaque material. The outer peripheral film CCF may include a material absorbing some light or absorbing some wavelengths of light. For example, the outer peripheral film CCF may include a dye or a pigment having an opaque color.

The second attachment layer ADH2 may be disposed on the support layer SPT and the outer peripheral film CCF. The second attachment layer ADH2 may include a material having adhesiveness like the first attachment layer ADH1. For example, the second attachment layer ADH2 may be defined as an adhesive. For example, the second attachment layer ADH2 may include a transparent adhesive such as a pressure sensitive adhesive (PSA) and/or an optically clear adhesive (OCA). The second attachment layer ADH2 may include an acrylic adhesive. In some embodiments, the second attachment layer ADH2 may be a transparent layer.

Areas of the first attachment layer ADH1 and the second attachment layer ADH2 may be greater than an area of the support layer SPT in plan view. The first attachment layer ADH1 and the second attachment layer ADH2 may be layers of which functions, materials, shapes, and the like, are substantially the same as each other. Accordingly, the spacer SPC may be vertically symmetrical with respect to the third direction DR3.

In case that the first attachment layer ADH1 and the second attachment layer ADH2 are the transparent layers and the outer peripheral film CCF includes the opaque material, the spacer SPC may appear as illustrated in FIG. 13. For example, when the spacer SPC is viewed from above, the second attachment layer ADH2 may be positioned on the upper side but may be transparent, and thus, a form in which the opaque outer peripheral film CCF surrounds the support layer SPT may be observed.

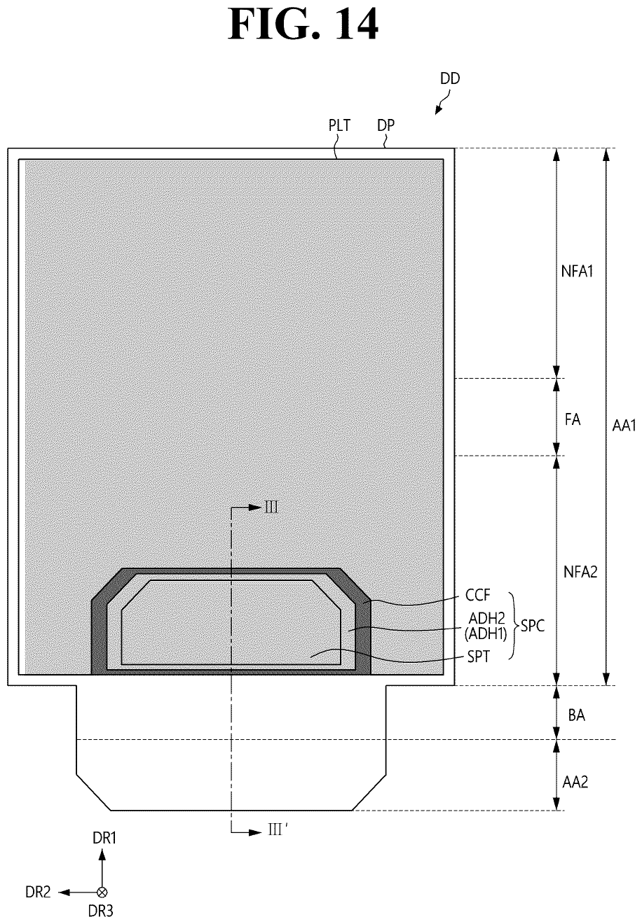

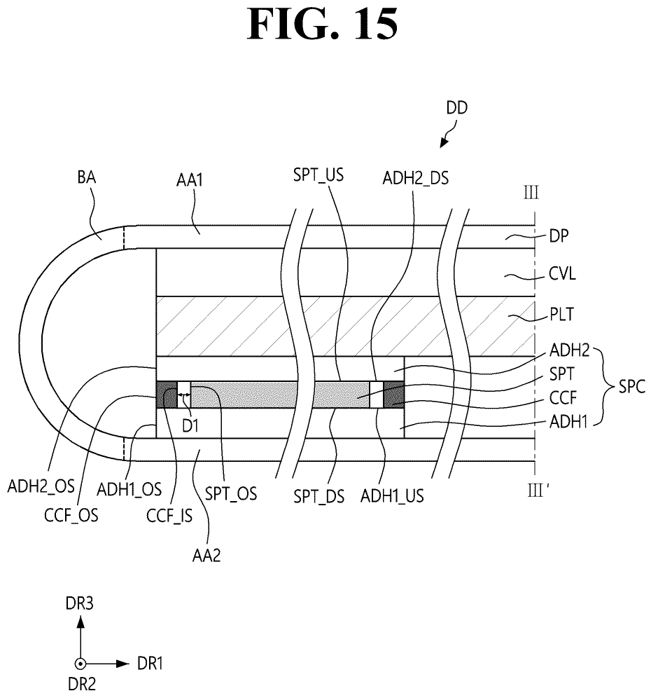

FIG. 14 is a schematic bottom view of a display panel, a panel support member, and the spacer according to an embodiment. FIG. 15 is a schematic cross-sectional view taken along line III-III′ of FIG. 14 in the second state.

FIG. 14 is a view obtained by inverting the display device DD illustrated in FIG. 5 by 180° with the first direction DR1 as an axis, and is a bottom view of the display device DD. However, in FIGS. 14 and 15, other members of the display device DD have been omitted, and only the display panel DP, the cover layer CVL, the plate PLT, and the spacer SPC have been illustrated. Components such as the bending protection layer BPL and the panel protection layer PPL may be omitted even in an actual product, as illustrated in FIG. 15, and all components may be included as in FIG. 10 described above, and thus, the disclosure is not limited to any one embodiment. However, hereinafter, for convenience of explanation, a case where the bending protection layer BPL and the panel protection layer PPL are omitted will be described by way of example.

Referring to FIGS. 14 and 15 in addition to FIGS. 11 to 13, the spacer SPC may be disposed on a rear surface, for example, a bottom surface, of the display device DD. In plan view, a size of the spacer SPC may be smaller than a size of the plate PLT. The spacer SPC may be disposed adjacent to the bending area BA based on the first direction DR1 in plan view.

The spacer SPC may be disposed on the plate PLT. The spacer SPC may overlap the plate PLT in the third direction DR3 and may be disposed below the plate PLT in FIG. 15. It has been illustrated in FIG. 15 that the spacer SPC is attached to the plate PLT so that the first attachment layer ADH1 is disposed on the lower side and the second attachment layer ADH2 is disposed on the upper side, but the disclosure is not limited thereto, and the spacer SPC may also be attached to the plate PTL so that the first attachment layer ADH1 is disposed on the upper side and the second attachment layer ADH2 is disposed on the lower side.

Referring to FIG. 14, the spacer SPC may have a shape substantially similar to a shape of the second area AA2 of the display panel DP in plan view. As illustrated in FIG. 15, in case that the second area AA2 and the spacer SPC overlap each other by bending of the bending area BA, the spacer SPC may overlap most of the second area AA2.

In a related embodiment, in case that the support layer SPT of the spacer SPC includes a transparent material such as polyethylene terephthalate (PET), all of the first attachment layer ADH1, the support layer SPT, and the second attachment layer ADH2 may be transparent, and thus, the spacer SPC may be transparent as a whole. A position of the spacer SPC may not be clearly viewed on the plate PLT by the naked eyes, a vision device, or the like.

In another related embodiment, in case that the support layer SPT of the spacer SPC includes a stainless steel metal such as SUS or STS, both the support layer SPT and the plate PLT may include a metal material and have similar brightness. Thus, a position of the spacer SPC may not be clearly viewed on the plate PLT by the naked eyes, a vision device, or the like.

On the other hand, in the display device DD according to an embodiment, the outer peripheral film CCF of the spacer SPC may have brightness different than that of the plate PLT. For example, the outer peripheral film CCF of the spacer SPC includes the opaque material and is disposed along an outer edge of the spacer SPC, and thus, a position of the spacer SPC may be clearly viewed by the naked eyes, a vision device, or the like.

Referring to FIGS. 11 and 15, an outer surface ADH1_OS of the first attachment layer ADH1, an outer surface CCF_OS of the outer peripheral film CCF, and an outer surface ADH2_OS of the second attachment layer ADH2 may be aligned with each other. The outer surface ADH1_OS of the first attachment layer ADH1 and the outer surface ADH2_OS of the second attachment layer ADH2 may protrude beyond an outer surface SPT_OS of the support layer SPT. For example, the outer surface SPT_OS of the support layer SPT may be positioned inside an inner surface CCF_IS of the outer peripheral film CCF. For example, a spaced distance D1 between the outer surface SPT_OS of the support layer SPT and the inner surface CCF_IS of the outer peripheral film CCF may be within approximately 0.5 mm. The spaced distance D1 may refer to an average value of the shortest distance from one point on the outer surface SPT_OS of the support layer SPT to the inner surface CCF_IS of the outer peripheral film CCF.

An entirety of a lower surface SPT_DS of the support layer SPT may be in direct contact with an upper surface ADH1_US of the first attachment layer ADH1. An entirety of an upper surface SPT_US of the support layer SPT may be in direct contact with a lower surface ADH2_DS of the second attachment layer ADH2.

In the display device DD according to an embodiment, the outer surface SPT_OS of the support layer SPT is positioned inside the inner surface CCF_IS of the outer peripheral film CCF, and thus, the support layer SPT having relatively high hardness may not be cut in a cutting process of a method S1 of manufacturing a display device to be described later. Accordingly, the first attachment layer ADH1, the outer peripheral film CCF, and the second attachment layer ADH2 excluding the support layer SPT may be cut at a time, such that a process time may be shortened and process yield and efficiency may be improved.

In a related embodiment, in case that the first attachment layer ADH1, the outer peripheral film CCF, and the second attachment layer ADH2 are not cut at a time, but are cut respectively and attached to each other, a margin for an attachment process should be secured along the first direction DR1 and the second direction DR2. Due to such a margin, a size of the first attachment layer ADH1 or the second attachment layer ADH2 may be smaller than a size of the support layer SPT. A step corresponding to a process margin may be formed in an area in which the first attachment layer ADH1 or the second attachment layer ADH2 does not overlap the support layer SPT. Such a step may cause deformation of members attached to upper and lower portions of the spacer SPC.

On the other hand, in the display device DD according to an embodiment, the first attachment layer ADH1 and the second attachment layer ADH2 may have an area greater than that of the support layer SPT in plan view and the outer surface ADH1_OS of the first attachment layer ADH1 and the outer surface ADH2_OS of the second attachment layer ADH2 protrude beyond the outer surface SPT_OS of the support layer SPT, and thus, the first attachment layer ADH1, the outer peripheral film CCF, and the second attachment layer ADH2 may be cut at a time. Accordingly, the step according to the attachment margin of the above-described related embodiment is eliminated, such that members attached to the upper and lower portions of the spacer SPC may be firmly supported.

Hereinafter, other embodiments of a display device according to an embodiment will be described. In the following embodiments, the same components as those of the above-described embodiment will be denoted by the same reference numerals, and an overlapping description thereof will be omitted or simplified and contents different from those described above will be described.

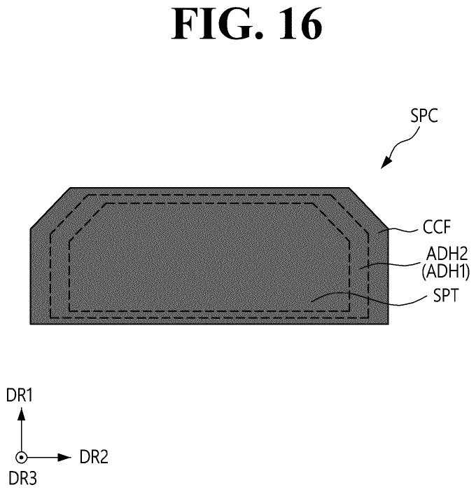

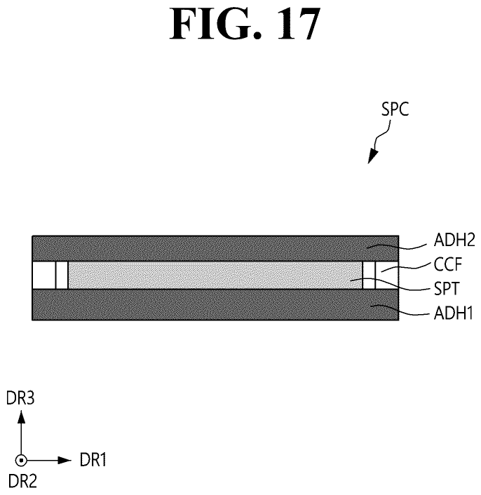

FIG. 16 is a schematic plan view of a spacer according to still another embodiment. FIG. 17 is a schematic cross-sectional view of the spacer according to still another embodiment.

Referring to FIGS. 16 and 17, a display device DD according to an embodiment may be different from the display device DD according to an embodiment described with reference to FIG. 13 at least in that the first attachment layer ADH1 and the second attachment layer ADH2 instead of the outer peripheral film CCF may have brightness different than that of the plate PLT.

More specifically, in an embodiment, the outer peripheral film CCF may be a transparent layer. On the other hand, the first attachment layer ADH1 and the second attachment layer ADH2 may be opaque layers. For example, the first attachment layer ADH1 and the second attachment layer ADH2 may include a material absorbing some light or absorbing some wavelengths of light. For example, the first attachment layer ADH1 and the second attachment layer ADH2 may include a dye or a pigment having an opaque color.

In case that the first attachment layer ADH1 and the second attachment layer ADH2 are the opaque layers and the outer peripheral film CCF includes a transparent material, the spacer SPC may appear as illustrated in FIG. 16. For example, when the spacer SPC is viewed from above, the spacer SPC may appear opaque as a whole because the second attachment layer ADH2 is positioned on the upper side and is opaque.

In the display device DD according to an embodiment, the first attachment layer ADH1 and the second attachment layer ADH2 may have brightness different than that of the plate PLT. For example, the first attachment layer ADH1 and the second attachment layer ADH2 of the spacer SPC include an opaque material, and thus, a position of the spacer SPC may be clearly viewed by the naked eyes, a vision device, or the like.

Only a case where both the first attachment layer ADH1 and the second attachment layer ADH2 are the opaque layers has been illustrated in FIGS. 16 and 17, but the disclosure is not limited thereto. For example, the same effect may be achieved even in case that only any one of the first attachment layer ADH1 and the second attachment layer ADH2 is opaque.

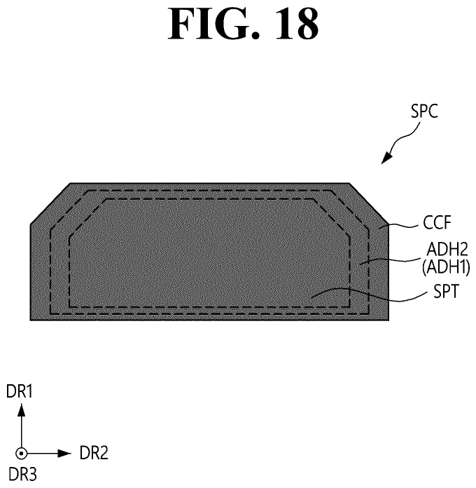

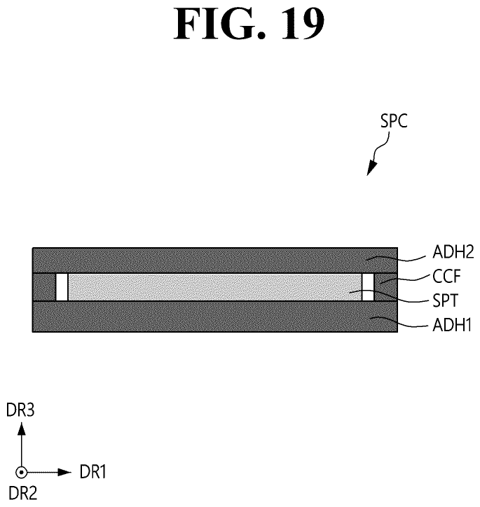

FIG. 18 is a schematic plan view of a spacer according to still another embodiment. FIG. 19 is a schematic cross-sectional view of the spacer according to still another embodiment.

Referring to FIGS. 18 and 19, a display device DD according to an embodiment may be different from the display device DD according to an embodiment described with reference to FIG. 13 at least in that the first attachment layer ADH1 and the second attachment layer ADH2 as well as the outer peripheral film CCF may have brightness different than that of the plate PLT.

More specifically, in an embodiment, all of the outer peripheral film CCF, the first attachment layer ADH1, and the second attachment layer ADH2 may be opaque layers. For example, the outer peripheral film CCF, the first attachment layer ADH1, and the second attachment layer ADH2 may include a material absorbing some light or absorbing some wavelengths of light. For example, the outer peripheral film CCF, the first attachment layer ADH1, and the second attachment layer ADH2 may include a dye or a pigment having an opaque color.

In case that the outer peripheral film CCF, the first attachment layer ADH1, and the second attachment layer ADH2 are the opaque layers, the spacer SPC may appear as illustrated in FIG. 18. For example, when the spacer SPC is viewed from above, the spacer SPC may appear opaque as a whole because the second attachment layer ADH2 is positioned on the upper side and is opaque.

In the display device DD according to an embodiment, the outer peripheral film CCF, the first attachment layer ADH1, and the second attachment layer ADH2 may have brightness different than that of the plate PLT. For example, the outer peripheral film CCF, the first attachment layer ADH1, and the second attachment layer ADH2 of the spacer SPC include an opaque material, and thus, a position of the spacer SPC may be clearly viewed by the naked eyes, a vision device, or the like.

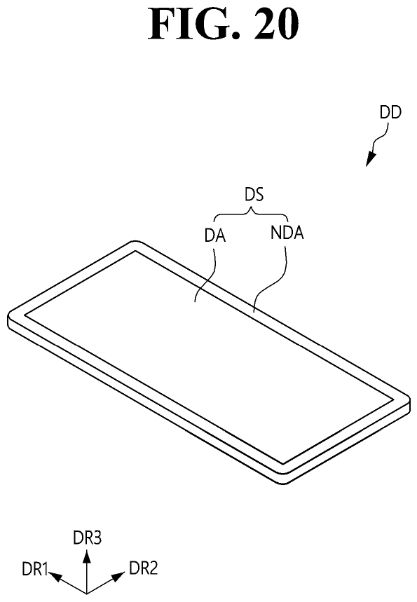

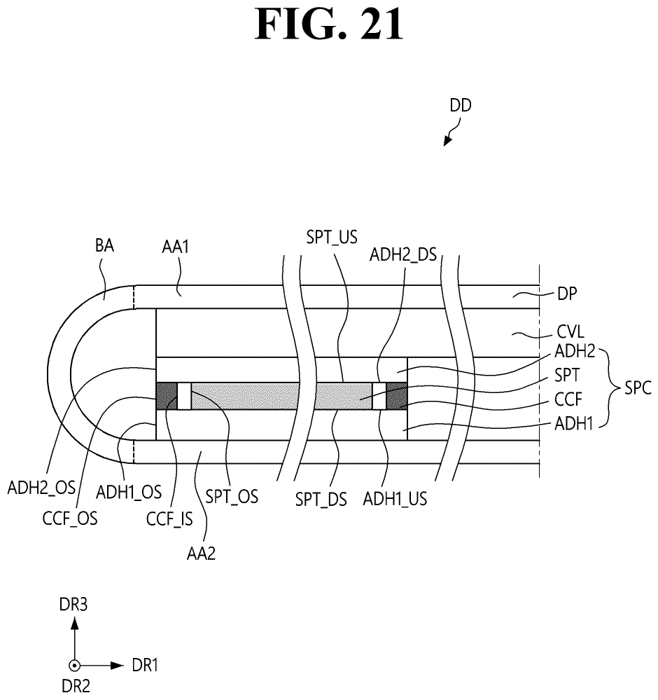

FIG. 20 is a schematic perspective view of a display device according to still another embodiment. FIG. 21 is a schematic cross-sectional view of the display device according to still another embodiment.

Referring to FIGS. 20 and 21, a display device DD according to an embodiment may be different from the display device DD according to an embodiment described with reference to FIG. 1 at least in that it may be a rigid display device DD.

More specifically, the display device DD according to an embodiment may be a rigid display device DD in which the display area DA is not folded or stretched. The display device DD according to an embodiment may not include the plate PLT unlike the foldable display device DD according to an embodiment.

Accordingly, the spacer SPC may be directly disposed on another surface, for example, the lower surface, of the cover layer CVL. For example, as illustrated in FIG. 21, the spacer SPC may be disposed between the cover layer CVL and the display panel DP. However, the disclosure is not limited thereto, and since the panel protection layer PPL (see FIG. 10) has been omitted in FIG. 21, in case that the panel protection layer PPL (see FIG. 10) is included, the spacer SPC may be disposed between the cover layer CVL and the second panel protection layer PPL2 (see FIG. 10).

Also in a case where the spacer SPC is directly disposed on the lower surface of the cover layer CVL according to the display device DD according to an embodiment, the first attachment layer ADH1, the outer peripheral film CCF, and the second attachment layer ADH2 excluding the support layer SPT may be cut at a time in a cutting process of a method S1 of manufacturing a display device to be described later, such that a process time may be shortened and process yield and efficiency may be improved, like the display device DD according to an embodiment described with reference to FIG. 1. Accordingly, the step according to the attachment margin of the related embodiment is eliminated, such that members attached to the upper and lower portions of the spacer SPC may be firmly supported.

Hereinafter, a method of manufacturing a display device according to an embodiment will be described.

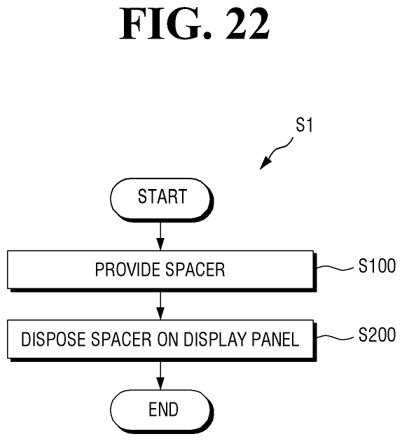

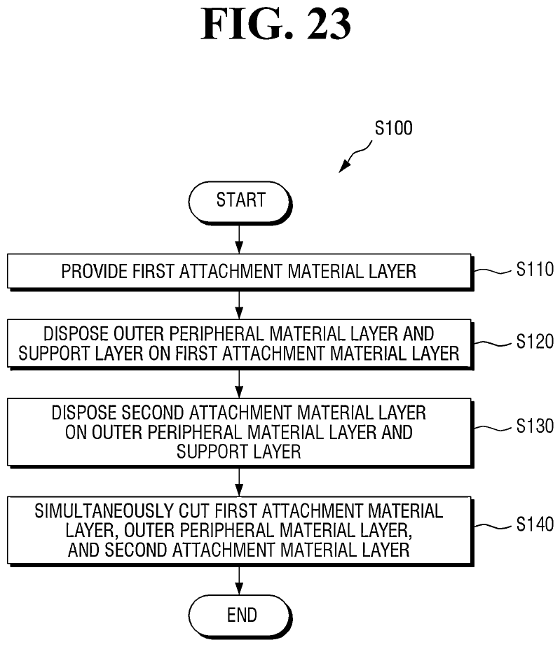

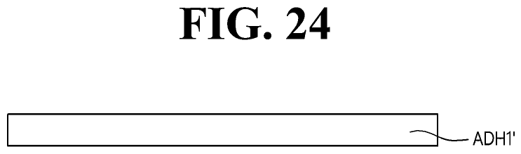

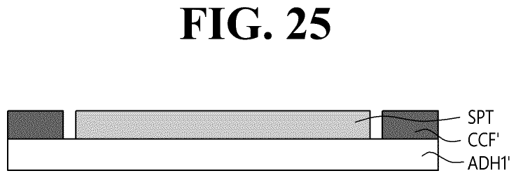

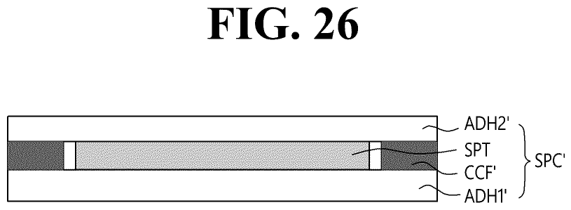

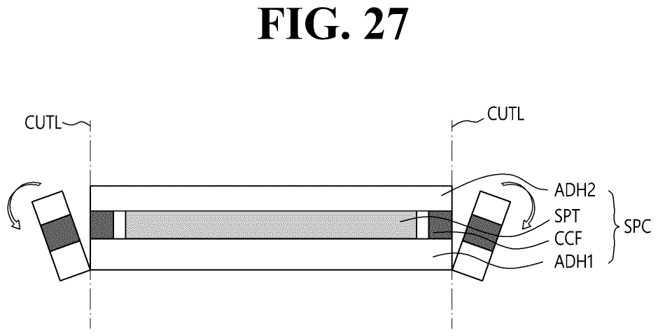

FIG. 22 is a flowchart illustrating a method of manufacturing a display device according to an embodiment. FIG. 23 is a flowchart illustrating S100 of FIG. 22. FIG. 24 is a schematic cross-sectional view illustrating S110 of FIG. 23. FIG. 25 is a schematic cross-sectional view illustrating S120 of FIG. 23. FIG. 26 is a schematic cross-sectional view illustrating S130 of FIG. 23. FIG. 27 is a schematic cross-sectional view illustrating S140 of FIG. 23.

Referring to FIGS. 22 to 27, a method (S1) of manufacturing a display device according to an embodiment may include providing a spacer (S100) and disposing the spacer on a display panel (S200).

First, the spacer SPC may be provided (S100).

The providing of the spacer (S100) may include providing a first attachment material layer (S110), disposing an outer peripheral material layer and a support layer on the first attachment material layer (S120), disposing a second attachment material layer on the outer peripheral material layer and the support layer (S130), and simultaneously cutting the first attachment material layer, the outer peripheral material layer, and the second attachment material layer (S140).

In the providing of the first attachment material layer (S110), the first attachment material layer ADH1′ may be provided. The first attachment material layer ADH1′ may be formed of a material having adhesiveness. For example, the first attachment material layer ADH1′ may be formed of a transparent adhesive such as a pressure sensitive adhesive (PSA) and/or an optically clear adhesive (OCA). The first attachment material layer ADH1′ may be formed of an acrylic adhesive.

In the disposing of the outer peripheral material layer and the support layer on the first attachment material layer (S120), the outer peripheral material layer CCF′ and the support layer SPT may be disposed on the first attachment material layer ADH1′.

The outer peripheral material layer CCF′ may be formed of a material having adhesiveness like the first attachment material layer ADH1′. For example, the outer peripheral material layer CCF′ may be formed of a transparent adhesive such as a pressure sensitive adhesive (PSA) and/or an optically clear adhesive (OCA). The outer peripheral material layer CCF′ may be formed of an acrylic adhesive.

The support layer SPT may be formed of a material having flexibility such as polyethylene terephthalate (PET). In another embodiment, the support layer SPT may be formed of a stainless steel metal such as SUS or STS for impact absorption and protection functions. Hardness of the support layer SPT may be greater than hardness of the first attachment material layer ADH1′, the outer peripheral material layer CCF′, and the second attachment material layer ADH2′.

In the disposing of the second attachment material layer on the outer peripheral material layer and the support layer (S130), the second attachment material layer ADH2′ may be disposed on the outer peripheral material layer CCF′ and the support layer SPT. The second attachment material layer ADH2′ may be formed of a material having adhesiveness like the first attachment material layer ADH1′. For example, the second attachment material layer ADH2′ may be formed of a transparent adhesive such as a pressure sensitive adhesive (PSA) and/or an optically clear adhesive (OCA). The second attachment material layer ADH2′ may be formed of an acrylic adhesive.

In the simultaneous cutting of the first attachment material layer, the outer peripheral material layer, and the second attachment material layer (S140), the first attachment material layer ADH1, the outer peripheral material layer CCF′, and the second attachment material layer ADH2′ are simultaneously cut, such that the first attachment layer ADH1, the outer peripheral film CCF, and the second attachment layer ADH2 may be formed.

For example, the first attachment material layer ADH1′, the outer peripheral material layer CCF′, and the second attachment material layer ADH2′ may be simultaneously cut along a cutting line CUTL. The simultaneous cutting of the first attachment material layer, the outer peripheral material layer, and the second attachment material layer may mean that the first attachment material layer, the outer peripheral material layer, and the second attachment material layer are cut at a time along the same cutting line CUTL.

After the spacer SPC is provided, the spacer SPC may be disposed on the display panel DP (see FIG. 10) (S200). As described above, the spacer SPC may be disposed below the cover layer CVL (see FIG. 21) or below the plate PLT (see FIG. 10), below the display panel DP (see FIG. 10). The disposition of the spacer SPC has been described above through the display devices according to the previous embodiments, and a detailed description thereof will thus be omitted.

According to a method S1 of manufacturing a display device according to an embodiment, an outer surface of the support layer SPT may be positioned inside an inner surface of the outer peripheral material layer CCF′, and thus, the support layer SPT having relatively high hardness may not be cut. Accordingly, the first attachment material layer ADH1′, the outer peripheral material layer CCF′, and the second attachment material layer ADH2′ excluding the support layer SPT may be cut at a time, such that a process time may be shortened and process yield and efficiency may be improved.

In concluding the detailed description, those skilled in the art will appreciate that many variations and modifications can be made to the embodiments without substantially departing from the principles of the disclosure. Therefore, the disclosed embodiments of the disclosure are used in a generic and descriptive sense only and not for purposes of limitation.

What is claimed is:

1. A display device, comprising:
a display panel including light emitting elements;
a panel support member disposed on a surface of the display panel; and
a spacer disposed on a surface of the panel support member, the spacer including:
a first attachment layer;
a support layer disposed on the first attachment layer;
an outer peripheral film disposed on the first attachment layer and surrounding the support layer, and
a second attachment layer disposed on the support layer and the outer peripheral film.

2. The display device of claim 1, wherein outer surfaces of the first attachment layer, the second attachment layer, and the outer peripheral film are aligned with each other.

3. The display device of claim 1, wherein the first attachment layer and the second attachment layer have an area greater in size than an area of the support layer in plan view.

4. The display device of claim 1, wherein outer surfaces of the first attachment layer and the second attachment layer protrude beyond an outer surface of the support layer.

5. The display device of claim 4, wherein
the support layer is spaced apart from the outer peripheral film, and
the outer surface of the support layer is disposed inside an inner surface of the outer peripheral film.

6. The display device of claim 5, wherein a spaced distance between the support layer and the outer peripheral film is within about 0.5 mm.

7. The display device of claim 1, wherein at least one of the first attachment layer, the second attachment layer, and the outer peripheral film has a brightness quality different from a brightness quality of the panel support member.

8. The display device of claim 7, wherein at least one of the first attachment layer, the second attachment layer, and the outer peripheral film includes a dye or a pigment having an opaque color.

9. The display device of claim 1, wherein an entirety of a lower surface of the support layer is in direct contact with an upper surface of the first attachment layer.

10. The display device of claim 1, wherein the support layer includes an SUS metal.

11. The display device of claim 1, wherein
the display panel includes:
a first area;
a second area; and
a bending area between the first area and the second area,
the bending area is bent so that the second area is disposed below the first area, and
the spacer is disposed to overlap the first area and the second area in a thickness direction.

12. The display device of claim 11, further comprising a panel protection member disposed between the display panel and the panel support member, wherein
the panel protection member includes a first panel protection member and a second panel protection member that are spaced apart from each other,
the first panel protection member is disposed on the first area,
the second panel protection member is disposed on the second area, and
the first panel protection member and the second panel protection member overlap the outer peripheral film and the support layer in the thickness direction.

13. The display device of claim 12, wherein the second panel protection member is disposed between the spacer and the second area.

14. The display device of claim 11, wherein
a size of the spacer is smaller than a size of the panel support member, and
the spacer overlaps a portion of the panel support member in the thickness direction and is disposed adjacent to the bending area.

15. The display device of claim 1, further comprising:
a panel lower member disposed between the display panel and the panel support member,
wherein the panel lower member includes at least one of a barrier layer and a cushion layer.

16. The display device of claim 1, wherein the panel support member includes a metal plate.

17. The display device of claim 1, wherein the support layer has a hardness quality greater than a hardness quality of the first attachment layer, the second attachment layer, and the outer peripheral film.

18. A display device, comprising:
a display panel including:
a display area including light emitting elements; and
a non-display area disposed around the display area; and
a spacer disposed on a surface of the display panel, the spacer including:
a first attachment layer;
a support layer disposed on the first attachment layer;
an outer peripheral film disposed on the first attachment layer and surrounding the support layer, and
a second attachment layer disposed on the support layer and the outer peripheral film.

19. The display device of claim 18, wherein outer surfaces of the first attachment layer and the second attachment layer protrude beyond an outer surface of the support layer.

20. A method of manufacturing a display device, the display device including a display panel including light emitting elements, a panel support member disposed on a surface of the display panel, and a spacer disposed on a surface of the panel support member, the method comprising:
providing the spacer; and
disposing the spacer on the display panel,
wherein the providing of the spacer includes:
providing a first attachment material layer;
disposing an outer peripheral material layer and a support layer on the first attachment material layer;
disposing a second attachment material layer on the outer peripheral material layer and the support layer; and
simultaneously cutting the first attachment material layer, the outer peripheral material layer, and the second attachment material layer.
